(19) United States
(12) Patent Application Publication
(10) Pub. No.: US 2007/0262441 A1
(43) Pub. Date: Nov. 15, 2007

(54) Heat sink structure for embedded chips and method for fabricating the same

(76) Inventor: Chi-Ming Chen, Hsin-chu (TW)

Correspondence Address: SAWYER LAW GROUP LLP, P O BOX 51418, PALO ALTO, CA, 94303, US

(21) Appl. No.: 11/430,439

(22) Filed: May 9, 2006

(51) Int. Cl. H01L 23/34

(52) U.S. Cl. 257/706

(57) ABSTRACT

A heat sink structure for embedding chips and a method for fabricating the same are proposed. An external metal layer is formed on the surface of a chip with pads and a wafer backside heat conductive layer is formed on the inactive surface of the chip. At least one chip is embedded into one cavity of a circuit board. The circuit board integrated with at lease one chip is formed with a circuit layer and a heat dissipating layer. The circuit layer is connected to the external metal layer and the heat dissipating layer is connected to the wafer backside heat conductive layer of at least one chip, so as to electrically connect to the chip embedded into the circuit board. Thus, the chip is electrically connected to outer circuit and the heat generated during operation of the chip is conducted to exit.

### FIELD OF THE INVENTION

This invention relates to a heat sink structure for embedded chips and a method for fabricating the same, and more particularly, to a heat sink structure for embedded chips able to be embedded into a circuit board and a method for fabricating the heat sink structure.

### BACKGROUND OF THE INVENTION

In order to satisfy the demands of compact size, multi-function, high-speed and high-frequency, modern electronic components are designed to be highly integrated and have fast data processing capability. Therefore, printed circuit boards (PCB), and integrated circuits packaging substrate as well, are designed to have fine line and smaller conductive via. The size (including line width, line space, and aspect ratio) of layout of a modem PCB is reduced to 20 μm or even smaller from 100 μm a size of layout of a traditional PCB.

With the development of the electronic components to have better functionality and compact size, a lamination technique for PCBs has to bear the characteristics of thin thickness, multiple layers and high density. Therefore, a multiple-layered PCB embedded with passive components and more chips is introduced to the market.

However, if having more and more chips and operating in a high frequency, the electronic component generates more heat. The heat has to dissipated to a region outside of the chips effectively, to ensure the normal operation of the electronic component.

A substrate, which is generally made of epoxy resin, polyimide, cyanate ester, glass fiber, bismaleimide triazine (BT), or a blend of epoxy resin and glass fiber (FR5), is used to support a chip and dissipate heat generated by the chip to a region outside of the chip. U.S. Pat. No. 6,703,697 discloses installing IC chips on the substrate and/or a strengthened plate.

However, because the heat dissipating efficiency of the substrate is poor, and the chips are separated from one another by the substrate, the heat transmission of the chips suffer high resistance. In result, the heat can not be dissipated from the multiple layers of the PCB to the region outside of the chips. Moreover, the coefficients of thermal expansion (CTE) of the substrate and the IC chips are mismatch, so the IC chip and solder balls will be imposed by a thermal stress, so as to reduce the reliability.

Moreover, notches on a heat dissipating plate for wiring and bonding occupy a large area of the substrate, so a bonding area of the IC chip and the substrate is decreased, and heat generated by the chip can be dissipated to nowhere but stays in a region where the IC chip is adhered to the substrate. In other words, a peripheral region of the substrate can not dissipate the heat effectively.

Therefore, only the use of the substrate is not effective enough to dissipate the heat, so varieties of resolutions are presented.

For example, one of the resolutions installs more solder balls under the IC chip and on the substrate, to dissipate the heat via the solder balls. However, such the installation of more solder balls increases the cost. Another one of the resolutions integrates a heat dissipating member into the substrate, as shown in U.S. Pat. No. 6,706,562. However, the integration of the additional heat dissipating member into the substrate increases the bulk of the electronic component and is contradictory to the demand of compact size.

According to the prior art, a chip supporter manufacturer manufactures chip supporters (such as the substrate or a lead frame) used for a semiconductor device first, and a semiconductor package manufacturer performs a die-planting, a molding and a solder ball implanting process on the chip supporters, to produce the semiconductor device having certain functions demanded by users. Because the semiconductor device is manufactured by both the chip supporter manufacturers and the semiconductor package manufacturer, steps involved to manufacture the semiconductor device are complicated and hard to be integrated. Moreover, if the users need the semiconductor device to have more functions, both the chip supporter manufacturers and the semiconductor package manufacturer have to change their production lines.

Therefore, in view of the above-mentioned problems, how to reduce the risks and drawbacks made by the prior art, and solve the problems, such as high cost, low reliability and poor heat dissipating efficiency is becoming one of the most important issues in the art.

### SUMMARY OF THE INVENTION

In views of the above-mentioned problems of the prior art, it is a primary objective of the present invention to provide a heat sink structure for embedded chips and a method for fabricating the same. Therefore, conductive lines formed on chips act as a heat sink structure having an enlarged heat dissipating area, and the chips have better heat dissipating capabilities.

To achieve the above-mentioned and other objectives, a heat sink structure for embedded chips and a method for fabricating the same are provided according to the present invention. The method first provides a wafer having a first surface as an active surface, and a second surface as an inactive surface. A external metal layer is on the first surface of the wafer by an under via metallurgy (UVM) process. Therefore, the electrical pads of each of the chips formed by dicing the wafer have corresponding external metal layer.

The method then installs the first surface of the wafer on a flat plate. Before installing the first surface of the wafer on the flat plate, the method forms an engaging layer on the whole first surface of the wafer. The engaging layer is covered on the external metal layer, and the first surface of the wafer is installed on the flat plate via the engaging layer.

The method performs a wafer backside channel process on the second surface of the wafer, to form a plurality of blind holes on a plurality of wafer backside regions, and a conductive layer on the second surface of the wafer and in the blind holes. After forming the wafer backside heat conductive layer on the second surface of the wafer, the method grinds the wafer, so as to strengthen the heat dissipating efficiency of the wafer.

The method then remove the flat plate, and dices the wafer into a plurality of chips. Each of the diced chips can be inserted into an opening of a circuit board, and can be therefore integrated with the circuit board.

The method then performs an insulating layer compressing and opening forming process on a bottom and top surface of the circuit board and chip to form an insulating layer, and takes the use of a laser drill technique, an exposure development technique, or a plasma etch technique to remove part of the insulating layer to form a plurality of insulating layer openings on the insulating layer. At least one of the insulating layer openings is formed corresponding to the external metal layer of the chip and the part of the wafer backside heat conductive layer, for exposing the electrical pads of the chip and the part of the wafer backside heat conductive layer.

The method then forms a circuit layer and a heat dissipating layer on the external metal layer and the wafer backside heat conductive respectively, so as to form a chip heat sink structure on the circuit board. The chip heat sink structure utilizes the heat dissipating layer to connect a chip, and dissipates heat generated by the chip to a region outside of the chip.

Since the present invention embeds the chips into the circuit board, and forms the chip heat sink structure formed by the wafer backside heat conductive layer connected to the chip for dissipating heat, the drawbacks of the prior art that the substrate has a poor heat dissipating efficiency and the heat can not be dissipated effectively due to a high resistance when the substrate transmits heat to the chip can be solved. Moreover, the present invention further solve the problem of low reliability due to the mismatch of thermal expansion coefficients of the substrate and the IC chip.

Of course, a solder mask can also be formed on the insulating layer. The solder mask is defined to have a plurality of solder mask openings for the circuit layer and the heat dissipating layer to be exposed through and connected to external devices. If the heat dissipating layer is not coated with the solder mask and contact with air, the heat sink structure has a better heat dissipating efficiency. The method performs a circuit build-up process iteratively to form another circuit layer and heat dissipating layer on the external meal layer and the wafer backside heat conductive layer.

Therefore, both the circuit layer and the heat dissipating layer can be connected to external devices. The method further dices the circuit board into a plurality of circuit board units for chips to be embedded into.

According to the above descriptions, the heat sink structure for embedded chips has a semiconductor chip, an external metal layer formed on the active surface of the chip, and a wafer backside heat conductive layer formed on the inactive surface of the chip.

The inactive surface of the chip has a plurality of blind holes covered by the wafer backside heat conductive layer. Each of the blind holes is smaller than or equal to the chip in depth. The wafer backside heat conductive layer has a first seed layer and a first metal layer covered on the first seed layer. The first seed layer is formed on the second surface of the chip and on the surface of the blind holes.

The present invention further provides a circuit board having the above-mentioned chip heat sink structure. The heat sink structure of the circuit board has at least one cavity installed in the circuit board, at least one chip integrated into the cavity of the circuit board and having an active surface and an inactive surface, an external metal layer formed on the active surface of the chip, a wafer backside heat conductive layer formed on the inactive surface of the chip, an insulating layer formed on a surface of the circuit board of the inactive surface of the chip and covered on the wafer backside heat conductive layer, a plurality of insulating layer openings, and a heat dissipating layer formed on portion of the insulating layer and in the insulating layer openings for the wafer backside heat conductive layer to be connected to external devices and to transmit the generated by the operating chip to a region outside of the chip.

The heat sink structure further has another insulating layer formed on the active surface of the chip of the circuit board and covered on the external metal layer. The insulating layer has a plurality of openings corresponding to the external metal layer. The heat sink structure further has a circuit layer formed in the openings of the insulating layer on the external metal layer and connected to the external metal layer.

An adhesive is injected into gaps between the chip and the cavities of the circuit board for adhering the chip to the cavities of the circuit board. The heat dissipating layer is extended and connected to the wafer backside heat conductive layer of at least a chip for connecting to the chip embedded into the circuit board.

Since the heat sink structure, which is formed by the chip itself, has the efficiency to dissipate the heat generated by the operating chip to a region outside of the chip, the heat sink structure enlarges the heat dissipating area of the chip and improve the heat dissipating efficiency of the chip. Therefore, the problem of the prior art that relying on the substrate only to dissipate heat is solved. Moreover, the present invention does not have the problems of the prior art that having to adopt more solder balls and integrate other heat dissipating component and having too high the cost and too big the circuit layout and volume.

### BRIEF DESCRIPTION OF DRAWINGS

The invention can be more fully understood by reading the following detailed description of the preferred embodiments, with reference made to the accompanying drawings, wherein:

FIGS. 1-10 are ten schematic diagrams illustrating a heat sink structure for embedded chips and a method for fabricating the same of the preferred embodiment according to the present invention.

### DETAILED DESCRIPTION OF PREFERRED EMBODIMENTS

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

FIGS. 1-10 are ten schematic diagrams illustrating a heat sink structure for embedded chips and a method for fabricating the same of the preferred embodiment according to the present invention.

As shown in FIG. 1, the method first provides a wafer 1. The wafer 1 comprises a first surface 11 and a second surface 13. The first surface 11 is defined as an active surface, and the second surface 13 is defined as an inactive surface. A plurality of external metal layers 111 are formed on a plurality of electrical pads of the first surface 11 of the wafer 1 by an under via metallurgy (UVM) process, such as a sputtering technique, a evaporation technique or a plating technique, etc, which are all prior arts and further description are hereby omitted. Each of external metal layers 111 is one selected from the group consisting a variety of metal layers, such as nickel-gold-copper, titanium-copper, titanium-nickel, or vanadium-copper, etc.

Though the present invention adopts two semiconductor components and four blind holes installed between the semiconductor components as an exemplary embodiment, it should be noted that the preferred embodiment is used, but not limited, to illustrate the heat sink structure and method of the present invention.

Please refer to FIG. 2. The method forms an engaging layer 5 on the first surface 11 to cover the external metal layers 111 completely, allowing the first surface 111 to be engaged by the engaging layer 5 with a flat plate 3, such as a sapphire plate, or any other tapes. By grinding the wafer 1, the wafer 1 can have a better heat dissipation efficiency. According to the preferred embodiment, the engaging layer 5 is made of a layer of liquid wax. The liquid wax melts and evaporates in a high temperature environment, and solidifies in a low temperature environment, which helps the engaging layer 5 to be adhered to or detached from the flat plate 3 easily.

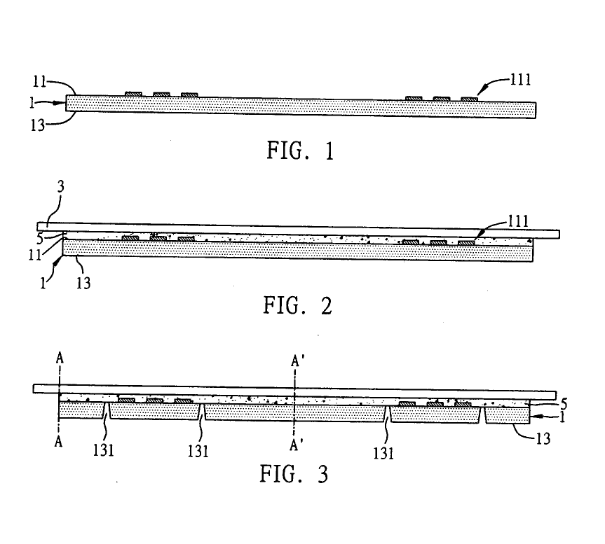

Please refer to FIG. 3. The method performs a wafer backside via process on the second surface 13 of the wafer 1, to form a plurality of blind holes 131 on a plurality of wafer backside regions. Each of the blind holes 131 is smaller than or equal to the grinding wafer 1 in depth.

Though each of the blind holes 131 is designed smaller than or equal to the grinding wafer 1 in depth and is protruded to a region outside of the engaging layer 5, so as to enlarge the area of heat dissipating channels formed in a succeeding process, it should be noted that each of the blind holes 131 can have another depth and width to satisfy a variety of demands.

According to the preferred embodiment, the method adopts a lithography etching technique to form the blind holes 131. The lithography etching technique is prior art, so further descriptions are hereby omitted.

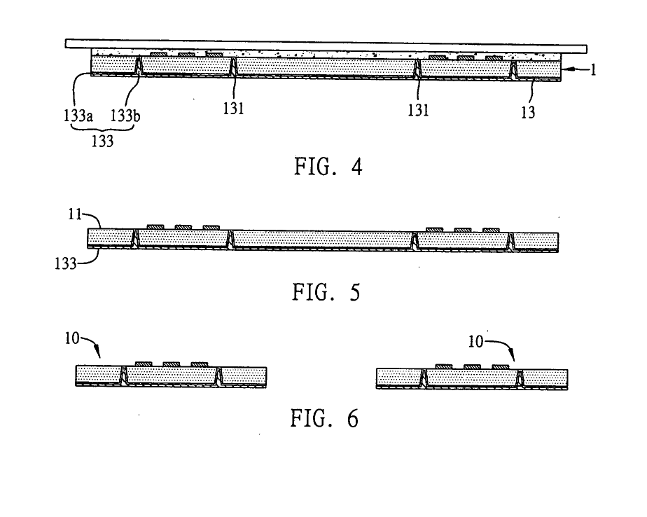

Please refer to FIG. 4. The method forms a wafer backside heat conductive layer 133 between the second surface 13 of the wafer 1 and the blind holes 131. The wafer backside heat conductive layer 133 comprises a first seed layer 133a, and a first metal layer 133b formed by electroplating the first seed layer 133a and covered between the second surface 13 of the wafer 1 and the blind holes 131. According to the preferred embodiment, the first seed layer 133a is made of titanium, copper, or other conductive polymers, and the first metal layer 133b is made of copper, gold, or other metal materials having good heat dissipating capabilities. Moreover, because both the first seed layer 133a and the first metal layer 133b have a metal structure, they can combine to serve as a good heat sink structure for a wafer backside.

Please refer to FIG. 5. The method peels the flat plate 3 from the first surface 11 of the wafer 1, and leaves the external metal layer 111 to be exposed on the wafer 1. According to the preferred embodiment, the method peels the flat plate 3 from the first surface 11 of the wafer 1 by heating and melting the engaging layer 5 if the engaging layer 5 is the liquid wax. Of course, in the present invention, the substrate 3 can be peeled from the first surface 11 of the wafer 1 by other methods, such as heating the flat plate 3 or the uses of hot water, acid solution and alkali solution, in accordance with the material of the flat plate 3.

Please refer to FIG. 6. The method dices the wafer 1 into a plurality of chips 10, each of which comprises the external metal layer 111 and the wafer backside heat conductive layer 133.

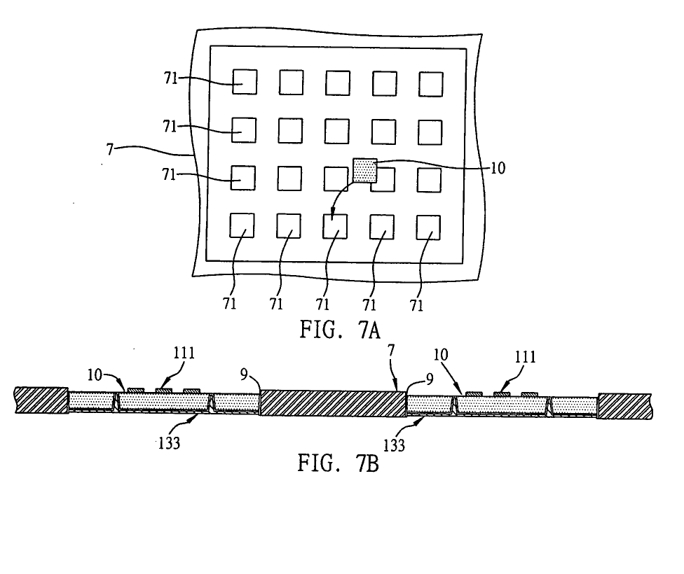

Please refer to FIGS. 7A and 7B. The method embeds a plurality of the chips 10 in a circuit board 7 having a plurality of cavities 71 for accommodating the chips 10, each of the cavities 71 having a radius slightly larger than a size of any one of the chips 10. The method then injects adhesive 9 such as liquid glue made of a thermosetting material into gaps between the chips 10 and the cavities 71 of the circuit board 7, and toasts the injected adhesive 9, so as to adhere the chips 10 to the circuit board 7.

As a whole, the circuit board structure comprises the chips 10, the external metal layers 111, which are formed on the active surfaces of the chips 10, and the wafer backside heat conductive layers 133, which are formed on the inactive surfaces of the chips 10, and the gaps between the chips 10 and the cavities 71 are adhered by the adhesive 9.

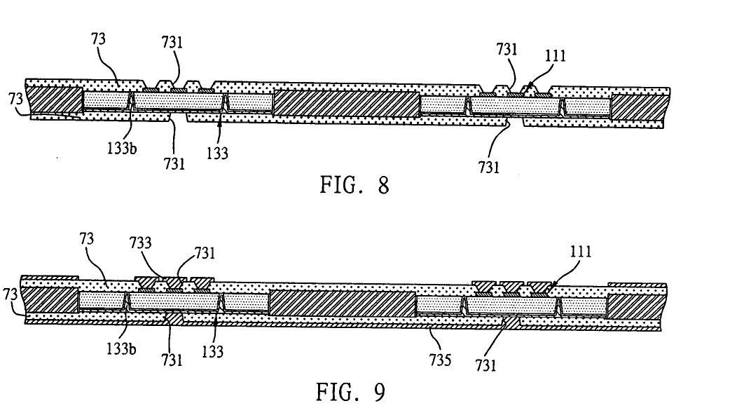

Please refer to FIG. 8. The method further compresses two insulating layers 73 on a top surface and a bottom surface of the circuit board 7 and chip 10 respectively. A plurality of insulating layer openings 731 are formed by removing part of the insulating layers 73 through the use of a laser drill technique, an exposure development technique and a plasma etching technique. The openings 731 correspond to the external metal layers 111 of the chips 10 and part of the wafer backside heat conductive layers 133, for exposing the external metal layers 111 of the chips 10 and the part of the wafer backside heat conductive layer 133. At least one of the insulating layers 73 is made of non-fibrous resin, such as Ajinomoto build-up film (ABF) or polypropylene (PP), or of fibrous impregnated resin, such as Bismaleimide Taiazine (BT) added by fiber glass or epoxy resin blended with fiber glass (FR4) or photosensitive insulating layer.

However, if adopting the laser drill technique to remove the part of the insulating layers 73, the method has to further adopt a de-smear process to de-smear residual glue dregs in the openings 731 due to the adoption of the laser drill process. On the other hand, if the insulating layer 73 is made of a photosensitive insulating material, after executing the exposure development technique, the method has to further adopt a de-scum process to de-scum residues in the openings 731.

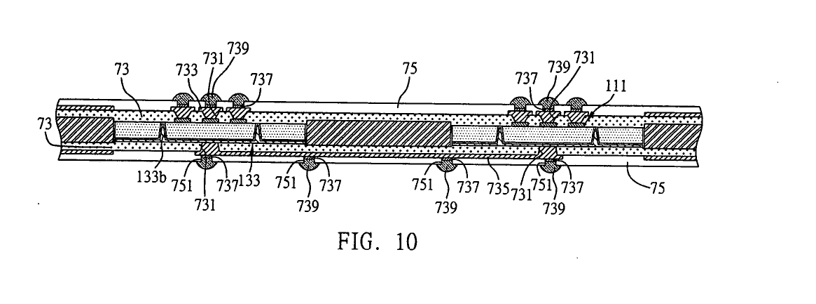

Please refer to FIG. 9. The method further adopts a patterned circuit layout process to form a plurality of circuit layers 733 and heat dissipating layers 735. According to the preferred embodiment, the circuit layers 733 are formed in the openings 731 of the external metal layers 111 by an electroplating technique, a electroless plating technique, a physical deposition technique, a chemical deposition technique, or other appropriate techniques, and the heat dissipating layers 735 are formed under and is connected to the part of the wafer backside heat conductive layer 133.

The circuit board structure thus comprises the chips 10, the external metal layers 111, which are formed on the active surfaces of the chips 10, the wafer backside heat conductive layers 133, which are formed on the inactive surfaces of the chips 10, the circuit layers 733, which are formed on part of the external metal layers 111, and the heat dissipating layers 735, which are formed on part of the wafer backside heat conductive layers 133. The heat dissipating layers 735 can be designed to be extended to a region connected to the heat dissipating layers 733 of at least two neighboring chips 10, and to be connected to at least, but not limited to, two chips 10.

Therefore, all of the chips 10, which are all embedded in the circuit board 7, can be connected the heat dissipating layers 735, and heat generated by the chips 10 can be dissipated via the heat dissipating layers 735 to a region outside of the wafer 1.

Please refer to FIG. 10. The method further forms a solder mask 75 on the insulating layer 73. The solder mask 75 is defined to have a plurality of solder mask openings 751, through which part of the circuit layers 733 and heat dissipating layers 735 are exposed to a region outside of the chips 10 and can be connected to external devices. Of course, the heat dissipating layers 735, if not covered by the solder mask 75, will have a better heat dissipating efficiency.

The method is allowed to form more than one layer of the insulating layers 73 and the heat dissipating layers 735 by iterating the steps illustrated in FIGS. 8 and 9. In other words, the method of the present invention is applicable to multiple-layered circuit boards.

The method then dices the circuit board 7 into a plurality of circuit board units.

Because each of the chips 10 has the wafer backside heat conductive layers 133, which are extended to a region around the semiconductor component and can be used to contact with those chips 10 having larger contact areas, the chips 10 thus have larger heat dissipating areas equivalently. Additionally, the heat dissipating layers 735, which are connected to the wafer backside heat conductive layers 133 of the chips 10, can be used, along with the wafer backside heat conductive layers 133, for dissipating the heat generated by the operating chips 10 to a region outside of the wafer 1 effectively.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A heat sink structure for an embedded chip, the heat sink structure comprising:
at least one cavity installed in a circuit board;
at least one chip integrated into the cavity of the circuit board and having an active surface and an inactive surface;
a wafer backside heat conductive layer formed on the inactive surface of the chip;
a first insulating layer formed on a first surface of the circuit board corresponding to the inactive surface of the chip and covered on the wafer backside heat conductive layer;
a plurality of first openings formed on the first insulating layer; and
a heat dissipating layer formed on a portion of the insulating layer and in the openings for connecting the wafer backside heat conductive layer to an external device and dissipating heat generated by the chip to a region outside of the heat sink structure.

2. The heat sink structure of claim 1 further comprising a plurality of external metal layers formed on the active surface of the chip.

3. The heat sink structure of claim 2 further comprising:
a second insulating layer formed on a second surface of the circuit board corresponding to the active surface of the chip and covered on the external metal layer;
a plurality of second insulating openings corresponding to the external metal layer and formed on the second insulating layer; and
a circuit layer formed in at least one of the second insulating openings on the external metal layer and connected to the external metal layer.

4. The heat sink structure of claim 3 further comprising a solder mask installed on the second surface of the circuit board for exposing part of the circuit layer.

5. The heat sink structure of claim I further comprising adhesive injected into a gap between the chip and the cavity of the circuit board for adhering the chip in the opening of the circuit board.

6. The heat sink structure of claim 1 further comprising a plurality of blind holes installed on the inactive surface of the chip.

7. The heat sink structure of claim 6, wherein each of the blind holes is equal to the chip in depth.

8. The heat sink structure of claim 6, wherein each of the blind holes is smaller than the chip in depth.

9. The heat sink structure of claim 1, wherein the heat conductive layer comprises a first seed layer and a first metal layer covered on the first seed layer.

10. The heat sink structure of claim 9, wherein the first metal layer is a either copper layer or a gold layer.

11. The heat sink structure of claim 1, wherein the heat dissipating layer is extended to be connected to the wafer backside heat conductive layer of the chip.

12. The heat sink structure of claim 1, wherein the heat dissipating layer is extended to be connected to two wafer backside heat conductive layers of at least two neighboring chips.

13. The heat sink structure of claim 1 further comprising a solder mask installed on the first surface of the circuit board for exposing part of the heat dissipating layer.

14. A method for fabricating a heat sink structure for an embedded chip, the method comprising:
providing a wafer having an active surface and an inactive surface, and forming an external metal layer on the active surface;
installing the active surface of the wafer on a substrate;
forming a plurality of blind holes on the inactive surface and forming a wafer backside heat conductive layer on the inactive surface;
removing the substrate;
dicing the wafer into a plurality of chips;
embedding the chips into a circuit board;
performing an insulating layer compressing and opening forming process on a first surface and a second surface of the circuit board to form a first insulating layer and a second insulating layer; and
forming a circuit layer on the first insulating layer and a heat dissipating layer on the second insulating layer and connecting the circuit layer and the heat dissipating layer to the external metal layer and the wafer backside heat conductive layer respectively.

15. The method of claim 14 further comprising forming an engaging layer on the active surface of the wafer completely for covering the external metal layer before installing the active surface of the wafer on a flat plate, the active surface of the wafer being installed on the substrate via the engaging layer.

16. The method of claim 15, wherein the engaging layer is a liquid wax layer.

17. The method of claim 15, wherein the flat plate is a sapphire plate.

18. The method of claim 15, wherein moving the flat plate is implemented by one selected from the group consisting of heating the flat plate, and pouring on the flat plate with hot water, acid solution and alkali solution.

19. The method of claim 14 further comprising grinding the wafer before forming the wafer backside heat conductive layer on the inactive surface of the wafer.

20. The method of claim 14, wherein the wafer backside heat conductive layer comprises a first seed layer formed on the inactive surface of the chip and in the blind holes, and a first metal layer formed by electroplating the first seed layer and covered on the inactive surface of the wafer and the first seed layer in the blind holes.

21. The method of claim 14, wherein embedding the chips into a circuit board comprises injecting adhesive into gaps between the chips and a plurality of cavities of the circuit board.

22. The method of claim 14, wherein performing an insulating layer compressing and opening forming process is implemented by compressing a first and a second insulating layers respectively on a first and a second surfaces of the circuit board and forming a plurality of insulating layer openings on both of the insulating layers.

23. The method of claim 22, wherein the insulating layer openings are formed by one selected from the group consisting of a laser drill technique, an exposure development technique and a plasma etch technique.

24. The method of claim 14, wherein forming a circuit layer on the first insulating layer and a heat dissipating layer on the second insulating layer is implemented by a patterned circuit layout process.

25. The method of claim 14, wherein the heat dissipating layer is formed under the wafer backside heat conductive layer and is connected to part of the wafer backside heat conductive layer of at least one neighboring chip.

26. The method of claim 14 further comprising performing a circuit build-up process iteratively, the circuit build-up process forming a plurality of tin solders on top surfaces of the circuit layer and the heat dissipating layer after forming a last layer.

27. The method of claim 26, wherein the circuit build-up process comprises performing an insulating layer compressing and opening forming process.
